(19) United States
(12) Patent Application Publication
(10) Pub. No.: US 2026/0239917 A1
(43) Pub. Date: Aug. 13, 2026

(54) AIR CURTAIN DEVICE

(71) Applicant: Gudeng Precision Industrial Co., LTD., New Taipei City (TW)

(72) Inventors: Ming-Chien Chiu, New Taipei City (TW); Yung-Chin Pan, New Taipei City (TW); Chia-Ho Chuang, New Taipei City (TW); Kuo-Hua Lee, New Taipei City (TW); Xin-Yuan Huang, New Taipei City (TW); Po-Ting Lee, New Taipei City (TW)

(21) Appl. No.: 19/423,143

(22) Filed: Dec. 17, 2025

Related U.S. Application Data
(60) Provisional application No. 63/756,298, filed on Feb. 10, 2025.

(51) Int. Cl. H10P 72/10; H10P 72/00

(52) U.S. Cl. CPC H10P 72/1924; H10P 72/0402

(57) ABSTRACT

An air curtain device includes a first chamber, a second chamber, a third chamber, and a diffusion member. The first chamber is in fluid communication with a gas source and receives a gas. The second chamber is in fluid communication with the first chamber, and the third chamber is in fluid communication with the second chamber. The diffusion member is disposed between the second chamber and the third chamber and uniformly supplies the gas from the second chamber to the third chamber. The third chamber includes an internal flow channel having a first end and a second end. The first end is in fluid communication with the second chamber via the diffusion member. The second end is defined by an upright wall and an inclined wall. The air curtain device is configured to provide the gas toward a substrate carrier at an inclined angle through the second end.

### RELATED APPLICATIONS

This application claims priority to U.S. Provisional Patent Application, No. U.S. 63/756,298, by CHIU, et al., titled “AIR CURTAIN DEVICE,” filed on Feb. 10, 2025, which is hereby incorporated by reference in their entirety.

### BACKGROUND OF THE INVENTION

### Technical Field

The present invention relates to an air curtain device. More particularly, the present invention relates to an air curtain device that provides gas towards a substrate carrier.

### Description of Related Art

In the semiconductor industry, various types of substrates are widely used in processes related to the manufacture of semiconductor devices so that different semiconductor processes can be performed. During these processes, the substrates are accommodated in a substrate carrier to prevent collisions and contaminations from the external environment.

In order to access the substrates accommodated in the substrate carrier, the substrate carrier must first be placed on a load port equipment. Then, a door of the substrate carrier is opened so that a robotic arm may extend into the substrate carrier to retrieve the substrates. One known type of the load port equipment includes a Fan Filter Unit (FFU) disposed adjacent to the door of the substrate carrier. When the door of the substrate carrier is opened, the FFU is used to guide an airflow for controlling the amount of the particles in the micro-environment surrounding the load port equipment. However, the FFU is not provided with humidity-control functionality, so the humidity of the gas guided by the FFU is at the same level as that of the external environment, which is typically higher than the humidity inside the substrate carrier. Moreover, the FFU cannot effectively block air or other unclean gases from the external environment.

From the viewpoint of modern semiconductor process, it is necessary to maintain extremely low humidity inside the substrate carrier in order to achieve a better yield. However, when the door of the substrate carrier is opened on the load port equipment, the interior of the substrate carrier is exposed to the external environment, making humidity control considerably difficult. Even though it is known in the prior art to utilize a purging mechanism in combination with a diffusion plate to perform humidity control in the substrate carrier, the effectiveness of the mechanism is still limited.

Therefore, how to effectively control humidity when the door of the substrate carrier is opened remains an important technical issue that needs to be solved.

### SUMMARY

In view of the above-mentioned problems, the present invention is to provide an air curtain device configured to provide a gas toward a substrate carrier at an inclined angle, thereby preventing air from the external environment from entering the substrate carrier. In addition, when the door of the substrate carrier is opened on the load port equipment, the humidity inside the substrate carrier can be controlled.

According to one aspect of the invention, an air curtain device is provided. The air curtain device includes a first chamber, a second chamber, a third chamber, and a diffusion member. The first chamber is in fluid communication with a gas source and is configured to receive a gas. The second chamber is in fluid communication with the first chamber. The third chamber is in fluid communication with the second chamber. The diffusion member is disposed between the second chamber and the third chamber and is configured to uniformly supply the gas from the second chamber to the third chamber. The third chamber includes an internal flow channel having a first end and an opposite second end. The first end is in fluid communication with the second chamber via the diffusion member, and the second end is defined by an upright wall and an inclined wall. The air curtain device is configured to provide the gas toward a substrate carrier at an inclined angle through the second end.

In one embodiment, the first end of the internal flow channel has a greater cross-sectional area than the second end, such that the gas passing through the second end has a greater flow velocity than that passing through the first end.

In one embodiment, an included angle is formed between the inclined wall and the upright wall, and the inclined angle is defined by the included angle. The included angle is less than or equal to 20 degrees.

In a further embodiment, the included angle is less than or equal to 5 degrees and greater than or equal to 3 degrees.

In one embodiment, the air curtain device further includes a gas feeding tunnel disposed between the first chamber and the second chamber and tapered from the first chamber toward the second chamber so as to uniformly supply the gas from the first chamber to the second chamber.

In one embodiment, when the gas is provided toward the substrate carrier at the inclined angle through the second end, the gas is guided toward an exterior of the substrate carrier.

In one embodiment, the diffusion member is a porous diffusion plate.

In one embodiment, the air curtain device is adapted for use with a load port equipment. When the substrate carrier is supported and positioned on the load port equipment, the air curtain device is disposed above the substrate carrier and configured to provide the gas downward toward the substrate carrier.

According to another aspect of the invention, another air curtain device is provided. The air curtain device includes a gas inlet channel member, a cover, a gas feeding housing, and a diffusion member. The gas inlet channel member is in fluid communication with a gas source and is configured to receive a gas. The gas inlet channel member has a first chamber therein. The cover is disposed on a side of the gas inlet channel member and has a second chamber therein that is in fluid communication with the first chamber. The gas feeding housing is disposed on the side of the gas inlet channel member and is configured to join with the cover. The gas feeding housing has a third chamber therein that is in fluid communication with the second chamber. The diffusion member is disposed between the cover and the gas feeding housing and is configured to uniformly supply the gas from the second chamber to the third chamber. The third chamber includes an internal flow channel having a first end and an opposite second end. The first end is in fluid communication with the second chamber via the diffusion member, and the second end is defined by an upright wall and an inclined wall. The air curtain device is configured to provide the gas toward a substrate carrier at an inclined angle through the second end.

In one embodiment, the cover includes a gas feeding tunnel disposed between the first chamber and the second chamber and tapered from the first chamber toward the second chamber so as to uniformly supply the gas from the first chamber to the second chamber.

The air curtain device according to the embodiments of the invention includes a first chamber, a second chamber in fluid communication with the first chamber, and a third chamber in fluid communication with the second chamber. The second end of the internal flow channel is defined by the inclined wall and the upright wall. In this manner, the air curtain device is configured to provide the gas toward the substrate carrier at the inclined angle through the second end. Because the gas is provided toward the substrate carrier at the inclined angle, substrates accommodated inside the substrate carrier are less affected by the airflow of the gas, thereby reducing vibration of the substrates. Furthermore, the inclined-angle gas reduces the likelihood of air from the external environment entering the substrate carrier, which facilitates maintaining humidity control and cleanliness inside the substrate carrier.

### BRIEF DESCRIPTION OF DRAWINGS

The present invention can be more fully understood by reading the following detailed description of the embodiment, with reference made to the accompanying drawings as follows.

FIG. 1 is a schematic diagram of an air curtain device according to one embodiment of the invention.

FIG. 2 is a three-dimensional diagram of an air curtain device according to another embodiment of the invention.

FIG. 3 is a cross-sectional diagram of the air curtain device of FIG. 2.

FIG. 4 is a schematic diagram showing the flow velocity distribution of the gas inside the third chamber.

FIG. 5 is a schematic diagram of the air curtain device and a load port equipment.

FIG. 6 is a schematic diagram of the air curtain device providing the gas at different inclined angles.

FIG. 7 is a schematic diagram showing the relative position of the substrate accommodated in the substrate carrier.

FIG. 8 is a curve chart showing humidity changes over time at different detection positions on the substrates.

### DETAILED DESCRIPTION

The air curtain device of the embodiments of the present invention is configured to provide a gas toward a substrate carrier at an inclined angle. As a result, the substrates accommodated inside the substrate carrier are less affected by the airflow of the gas, and the likelihood of air from the external environment entering the substrate carrier is reduced.

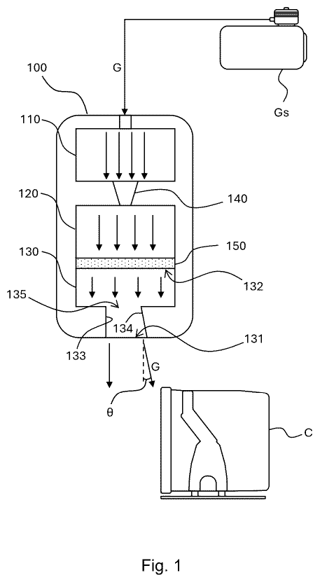

Please refer to FIG. 1, which is a schematic diagram of an air curtain device according to one embodiment of the invention. The air curtain device 100 of this embodiment includes a first chamber 110, a second chamber 120, a third chamber 130, and a diffusion member 150. The first chamber 110 is in fluid communication with a gas source Gs and is configured to receive a gas G. The second chamber 120 is in fluid communication with the first chamber 110, and the third chamber 130 is in fluid communication with the second chamber 120. The diffusion member 150 is disposed between the second chamber 120 and the third chamber 130 and is configured to uniformly supply the gas G from the second chamber 120 to the third chamber 130. The third chamber 130 includes an internal flow channel 135 having a first end 131 and an opposite second end 132. The first end 131 is in fluid communication with the second chamber 120 via the diffusion member 150, and the second end 132 is defined by an upright wall 133 and an inclined wall 134. The air curtain device 100 is configured to provide the gas G toward a substrate carrier C at an inclined angle θ through the second end 132. In one embodiment, the substrate carrier C is used to accommodate multiple substrates used in the field of semiconductor technology.

The air curtain device 100 of the present embodiment further includes a gas feeding tunnel 140 disposed between the first chamber 110 and the second chamber 120 and tapered from the first chamber 110 toward the second chamber 120, so as to uniformly supply the gas G from the first chamber 110 to the second chamber 120. Initially, when the gas G is supplied from the gas source Gs to the air curtain device 100, the flow velocity and pressure of the gas G is unstable. Without the first chamber 110, the gas G directly enters the second chamber 120 and passes through the diffusion member 150. In such case, problems like uneven airflow and non-uniform pressure distribution may occur, thereby affecting the uniformity of discharging the gas G from the air curtain device 100. In the present embodiment, the first chamber 110 functions as a buffer space when the gas G enters the air curtain device 100 and reduces fluctuations in flow velocity and pressure during the supply of the gas G. The gas G is allowed to diffuse adequately within the first chamber 110 so that a stable and uniform pressure distribution can be achieved. As a result, the problems like uneven airflow and non-uniform pressure distribution of the gas G before entering the gas feeding tunnel 140 are eliminated.

In addition, because the gas feeding tunnel 140 has a tapered structure, the gas G is gradually guided from a region having a larger cross-sectional area toward a region having a smaller cross-sectional area. In this manner, the flow velocity of the gas G can be increased and its flow direction can be concentrated, thereby achieving a flow-straightening effect. The gas G can enter the second chamber 120 from the first chamber 110 in a stable, uniform, and directionally consistent manner, causing the distribution of the gas G inside the second chamber 120 to be more uniform. As a result, the gas G can be uniformly supplied to the diffusion member 150 and then into the third chamber 130, thereby ensuring airflow stability and the quality of the air curtain provided by the air curtain device 100.

In the present embodiment, the first end 131 of the internal flow channel 135 of the third chamber 130 has a greater cross-sectional area than the second end 132, such that the flow velocity of the gas G passing through the second end 132 is greater than that passing through the first end 131. In this manner, the loss in flow velocity of the gas G after passing through the diffusion member 150 can be compensated, thereby increasing the discharge flow velocity of the gas G. When the air curtain device 100 provides the gas G at the inclined angle θ through the second end 132, the gas G can effectively block external air and prevent it from entering the substrate carrier C, which helps reduce humidity changes when the door of the substrate carrier C is opened and also helps prevent significant changes in cleanliness.

As described above, the second end 132 of the internal flow channel 135 of the third chamber 130 is defined by the upright wall 133 and the inclined wall 134. An included angle is formed between the inclined wall 134 and the upright wall 133. The inclined angle θ is defined by the included angle. More specifically, when the gas G exits the second end 132, one side of the airflow is discharged along the upright wall 133 (i.e., in a substantially vertical direction), while the other side of the airflow is discharged along the inclined wall 134 at the inclined angle θ. In one embodiment, when the air curtain device 100 provides the gas G toward the substrate carrier C at the inclined angle θ through the second end 132, the gas G is guided toward an exterior of the substrate carrier C, thereby preventing the airflow from affecting the substrates accommodated inside the substrate carrier C and reducing vibration of the substrates. In designing and manufacturing the upright wall 133 and the inclined wall 134 of the second end 132, in one embodiment, the included angle between the inclined wall 134 and the upright wall 133 is less than or equal to 20 degrees, which indicates that the maximum inclined angle θ of the gas G provided by the air curtain device 100 is 20 degrees. In a preferred embodiment, the included angle is less than or equal to 5 degrees and greater than or equal to 3 degrees, which means the inclined angle θ may be between 3 degrees and 5 degrees.

The diffusion member 150 of the present embodiment can be exemplified by a porous diffusion plate, such as a porous sintered material formed integrally as one piece. Applicable material may include, but is not limited to, ceramic materials and polymer-based materials. When the gas G enters the second chamber 120, its the pressure builds up to a designed threshold (also referred to as a saturated pressure). The gas G then uniformly permeates through the diffusion member 150 and maintains a stable pressure during supply of the gas G. As a result, the gas G uniformly enters the third chamber 130, which helps improve the uniformity of the gas G discharged through the second end 132.

In addition, the air curtain device 100 of the present embodiment is adapted for use with a load port equipment. When the substrate carrier C is supported and positioned on the load port equipment, the air curtain device 100 is disposed above the substrate carrier C and provides the gas G downward toward the substrate carrier C.

Furthermore, the flow velocity, pressure, or composition of the gas G of the embodiments of the invention are not limited herein. Purge gases commonly used in semiconductor processes may be supplied into the air curtain device 100. Applicable examples include, but are not limited to, nitrogen (N₂), hydrogen (Hz), and argon (Ar).

In the air curtain device according to the embodiments of the invention, the internal flow channel of the third chamber includes the first end and the second end, and the second end is defined by the upright wall and the inclined wall. The air curtain device provides the gas toward the substrate carrier at the inclined angle through the second end. Because the first end and the second end have different cross-sectional areas, the flow velocity of the gas G increases as it flows through the internal flow channel of the third chamber, thereby compensating for the loss in flow velocity caused by the diffusion member. In addition, by providing the gas G at the inclined angle, the substrates accommodated inside the substrate carrier are less affected by the gas flow, thereby reducing vibration of the substrates. Furthermore, by providing the gas G toward the substrate carrier at the inclined angle, the likelihood of external air entering the substrate carrier is reduced, which helps maintain humidity control inside the substrate carrier and prevent significant changes in cleanliness.

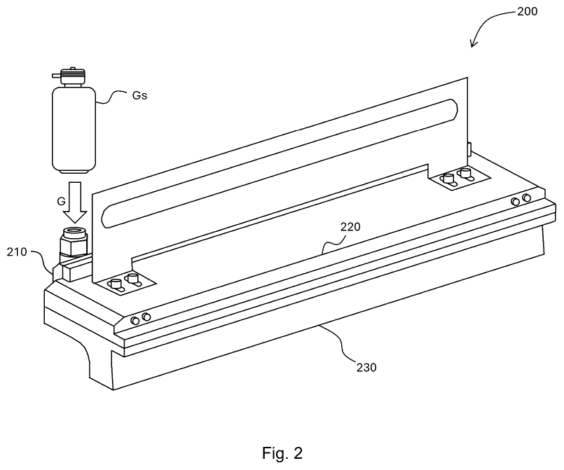

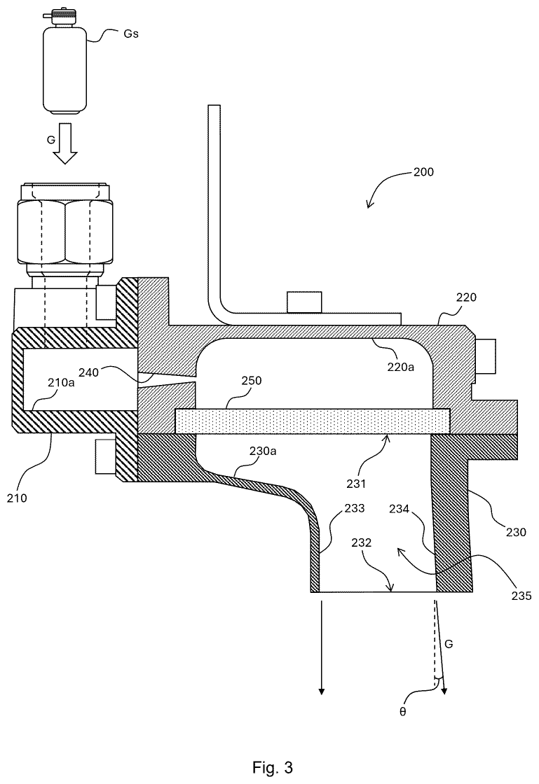

Please refer to FIG. 2 and FIG. 3. FIG. 2 is a three-dimensional diagram of an air curtain device according to another embodiment of the invention. FIG. 3 is a cross-sectional diagram of the air curtain device of FIG. 2. The air curtain device 200 includes a gas inlet channel member 210, a cover 220, a gas feeding housing 230, and a diffusion member 250. The gas inlet channel member 210 is in fluid communication with a gas source Gs and is configured to receive a gas G, and the gas inlet channel member 210 has a first chamber 210a therein. The cover 220 is disposed on a side of the gas inlet channel member 210 and has a second chamber 220a therein that is in fluid communication with the first chamber 210a. The gas feeding housing 230 is disposed on said side of the gas inlet channel member 210 and is configured to join with the cover 220. The gas feeding housing 230 has a third chamber 230a therein that is in fluid communication with the second chamber 220a. The diffusion member 250 is disposed between the cover 220 and the gas feeding housing 230 and is configured to uniformly supply the gas G from the second chamber 220a to the third chamber 230a. The third chamber 230a includes an internal flow channel 235 having a first end 231 and an opposite second end 232. The first end 231 is in fluid communication with the second chamber 220a via the diffusion member 250, and the second end 232 is defined by an upright wall 233 and an inclined wall 234. The air curtain device 200 is configured to provide the gas G toward a substrate carrier C at an inclined angle θ through the second end 232.

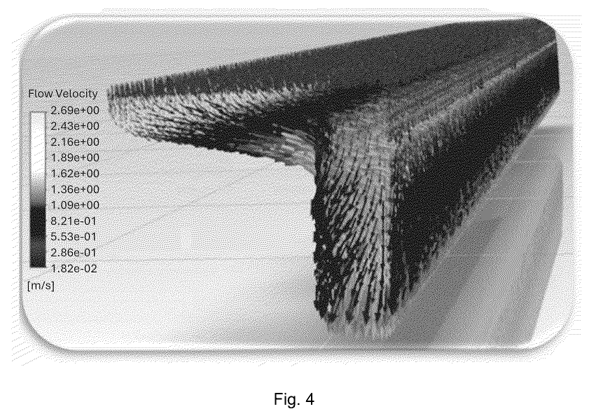

Please refer to FIG. 3 and FIG. 4. FIG. 4 is a schematic diagram showing the flow velocity distribution of the gas inside the third chamber. In the present embodiment, the first end 231 of the internal flow channel 235 has a greater cross-sectional area than the second end 232, such that the gas G passing through the second end 232 has a greater flow velocity than that passing through the first end 231. In this manner, the loss in flow velocity of the gas G after passing through the diffusion member 250 can be compensated, thereby increasing the discharge flow velocity of the gas G. In FIG. 4, the grayscale distribution reflects the local flow velocity, with lighter tonal regions corresponding to higher flow velocity and darker tonal regions indicating lower flow velocity. As shown in FIG. 4, the flow velocity distribution inside the third chamber 230a indicates that, at the first end 231 (the upper wider area in FIG. 4), the gas G enters the third chamber 230a at a flow velocity of approximately 1.82e-02 m/s, whereas at the second end 232 (the lower narrower area in FIG. 4), the flow velocity of the gas G increases to approximately 1.62e+00 m/s. The design of the internal flow channel 235 indeed effectively compensates for the loss of the flow velocity.

Please refer back to FIG. 3. The cover 220 of the air curtain device 200 further includes a gas feeding tunnel 240 that is in fluid communication with the first chamber 210a and the second chamber 220a and is tapered from the first chamber 210a toward the second chamber 220a so as to uniformly supply the gas G from the first chamber 210a to the second chamber 220a. The functions and technical features of the components of the air curtain device 200 of the present embodiment, including the first chamber 210a, the gas feeding tunnel 240, the second chamber 220a, the diffusion member 250, the third chamber 230a, and the internal flow channel 235, are the same as those described in the embodiment relating to FIG. 1. Their details will not be repeated here.

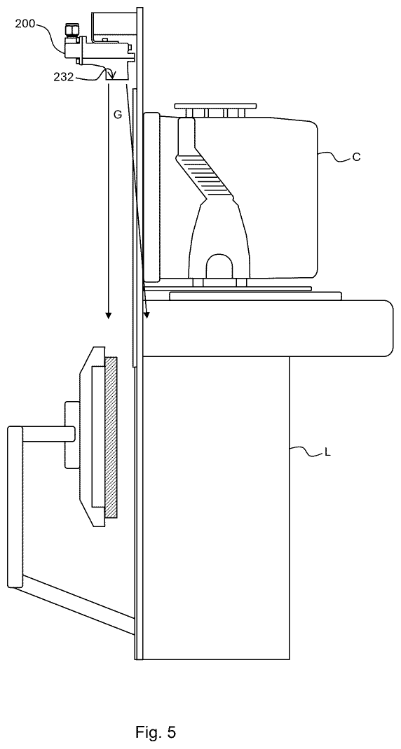

Please refer to FIG. 3 and FIG. 5. FIG. 5 is a schematic diagram of the air curtain device and a load port equipment. The air curtain device 200 of the present embodiment is adapted for use with the load port equipment L. When the substrate carrier C is supported and positioned on the load port equipment L, the air curtain device 200 is disposed above the substrate carrier C and provides the gas G downward toward the substrate carrier C. When the air curtain device 200 provides the gas G at the inclined angle θ through the second end 232, the gas G is guided toward an exterior of the substrate carrier C, thereby effectively blocking external air and preventing it from entering the substrate carrier C, thus achieving effective humidity control. Additionally, guiding the gas G at the inclined angle θ prevents the airflow from affecting the substrates accommodated in the substrate carrier C, thereby reducing vibration of the substrates. Also, the likelihood of particles and contaminants in the external environment entering the substrate carrier C is reduced, thereby reducing the significant changes in cleanliness.

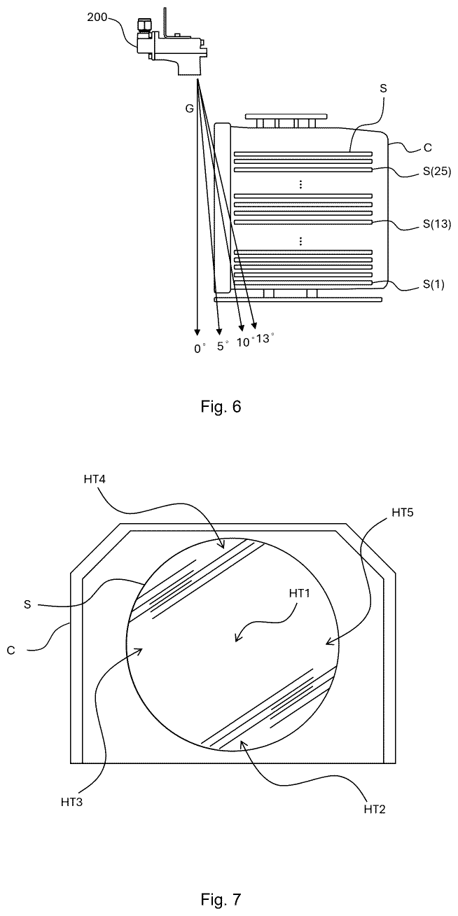

Experimental data are provided to show the effects of different inclined angles θ of the gas G on substrate vibration. Please refer to FIG. 3 and FIG. 6. FIG. 6 is a schematic diagram of the air curtain device providing the gas at different inclined angles. The air curtain device 200 can define different inclined angles θ by adjusting the included angle between the inclined wall 234 and the upright wall 233 (both shown in FIG. 3). In the experiment, substrate vibration amplitudes were measured at inclined angles θ of 0 degrees, 5 degrees, 10 degrees, and 13 degrees, and the experimental results were shown in Table 1. In Table 1, the label “Slot Number” indicates the slot position in which the substrate S is placed. For example, SLOT1 represents the substrate S(1) placed in the first slot (the lowest position), SLOT13 represents the substrate S(13) placed in the thirteenth slot, and so on. In the experiment, both the minimum vibration value and the maximum vibration value of each substrate S at its corresponding slot were measured, and the vibration amplitude of the substrate S is defined by the difference between the maximum value and minimum value.

TABLE 1

Inclined Angle
0°

| Slot Number | SLOT1 | SLOT13 | SLOT25 |
|---|---|---|---|
| Maximum Value | 0.628 | 0.630 | 0.628 |
| Minimum Value | 0.538 | 0.538 | 0.539 |
| Vibration Amplitude | 0.090 | 0.092 | 0.089 |

Inclined Angle
5°

| Slot Number | SLOT1 | SLOT13 | SLOT25 |
|---|---|---|---|
| Maximum Value | 0.624 | 0.634 | 0.630 |
| Minimum Value | 0.529 | 0.530 | 0.527 |
| Vibration Amplitude | 0.095 | 0.104 | 0.103 |

Inclined Angle
10°

| Slot Number | SLOT1 | SLOT13 | SLOT25 |
|---|---|---|---|
| Maximum Value | 0.645 | 0.628 | 0.640 |
| Minimum Value | 0.517 | 0.535 | 0.527 |
| Vibration Amplitude | 0.128 | 0.093 | 0.113 |

Inclined Angle
13°

| Slot Number | SLOT1 | SLOT13 | SLOT25 |
|---|---|---|---|
| Maximum Value | 0.639 | 0.650 | 0.637 |
| Minimum Value | 0.534 | 0.526 | 0.518 |
| Vibration Amplitude | 0.105 | 0.124 | 0.119 |

Based on Table 1, when the inclined angle θ is 0 degrees, the vibration amplitudes of the substrates S at all slots are the smallest, indicating that the substrates S are least affected by the airflow of the gas G. When the inclined angle θ is 5 degrees, the vibration amplitudes increase at all slots, suggesting that the airflow of the gas G induces additional vibration in the substrates S. When the inclined angle θ is increased to 10 degrees, the vibration amplitude of the substrate S(1) at SLOT1 increases significantly, indicating that the substrate S(1) is noticeably affected by the airflow of the gas G. When the inclined angle θ further increases to 13 degrees, the vibration amplitude of the substrate S(13) at SLOT13 increases significantly, indicating that the substrate S(13) is noticeably affected by the airflow of the gas G.

According to multiple experimental results, when the inclined angle θ is less than or equal to 20 degrees, the vibration amplitudes of the substrates S remain within an acceptable range. However, a preferable vibration performance is achieved when the inclined angle θ is less than or equal to 5 degrees. In this range, the substrates S are not significantly affected by the airflow of the gas G, thereby reducing vibration of the substrates S.

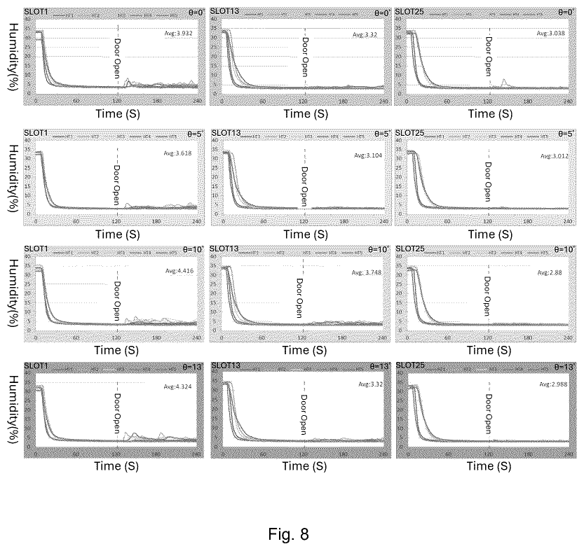

Another set of experimental data is further provided to show the effects of different inclined angles θ of the gas G on humidity inside the substrate carrier C. Please refer to FIG. 7 and FIG. 8. FIG. 7 is a schematic diagram showing the relative position of the substrate accommodated in the substrate carrier. FIG. 8 is a curve chart showing humidity changes over time at different detection positions on the substrates. In the experiment, firstly, multiple humidity detectors were disposed at five detection positions HT1-HT5 on each substrate S. Then, the door of the substrate carrier C was properly locked, and a purge process, which is not limited in the present invention, was performed inside the substrate carrier C, so that the humidity inside the substrate carrier C dropped to a stable low level. Thereafter, the door was opened at a predetermined time point, and the humidity change over time at each detection position HT1-HT5 was measured. In the experiment, the substrates S(1), S(13), and S(25) located at SLOT1, SLOT13, and SLOT25 (each substrate S at its corresponding slot is shown in FIG. 6) were subjected to humidity detections. The predetermined time point here is 120 seconds after the door was closed. In the curves shown in FIG. 8, the first row corresponds to the data obtained when the inclined angle θ is 0 degrees, the second row corresponds to the data obtained when the inclined angle θ is 5 degrees, the third row corresponds to the data obtained when the inclined angle θ is 10 degrees, and the fourth row corresponds to the data obtained when the inclined angle θ is 13 degrees. The first column corresponds to the data of the substrate S(1) at SLOT1, the second column corresponds to the data of the substrate S(13) at SLOT13, and the third column corresponds to the data of the substrate S(25) at SLOT25. In FIG. 8, the value “Avg” indicates an average value of humidity change, and “Slot Number” indicates the slot position in which the substrate S is placed.

According to the experimental results, when the inclined angle θ is 5 degrees, the average humidity change after the door is opened is 3.618% for the substrate S(1), 3.104% for the substrate S(13), and 3.012% for the substrate S(25). For inclined angles θ of 0 degrees, 10 degrees, and 13 degrees, the humidity changes are all greater than those at the inclined angle θ of 5 degrees. Based on multiple experimental results, when the inclined angle θ is less than or equal to 5 degrees and greater than or equal to 3 degrees, the gas G provided by the air curtain device 200 exhibits a preferable effect of reducing the humidity change.

By combining the experimental results of substrate vibration and humidity change as described above, it is shown that, based on the effects of different inclined angles θ of the gas G on both substrate vibration and humidity change in the substrate carrier C, a preferable inclined angle θ of the gas G discharged from the second end 232 of the air curtain device 200 (which is defined by the included angle between the inclined wall 234 and the upright wall 233) is less than or equal to 5 degrees and greater than or equal to 3 degrees.

The air curtain device according to embodiments of the present invention includes a first chamber, a second chamber, a third chamber, and a diffusion member. The first chamber is in fluid communication with a gas source and is configured to receive a gas. The second chamber is in fluid communication with the first chamber, and the third chamber is in fluid communication with the second chamber. The diffusion member is disposed between the second chamber and the third chamber and is configured to uniformly supply the gas from the second chamber to the third chamber. The third chamber includes an internal flow channel having a first end and an opposite second end. The first end is in fluid communication with the second chamber via the diffusion member, and the second end is defined by an upright wall and an inclined wall. The air curtain device is configured to provide the gas toward a substrate carrier at an inclined angle through the second end. Because the gas is provided at the inclined angle, the substrates accommodated inside the substrate carrier are prevented from being affected by the airflow of the gas, thereby reducing vibration of the substrates. Furthermore, by guiding the gas at the inclined angle, the likelihood of external air entering the substrate carrier is reduced, which helps maintain humidity control inside the substrate carrier and improves cleanliness.

Although the present invention has been disclosed with a number of embodiments as above, they are not intended to limit the present invention. Any person skilled in the art can make various modifications and refinements without departing from the spirit and scope of the present invention. Therefore, the protection scope of the present invention shall be defined by the scope of the appended claims.

What is claimed is:

1. An air curtain device, comprising:
a first chamber being in fluid communication with a gas source and configured to receive a gas;
a second chamber being in fluid communication with the first chamber;
a third chamber being in fluid communication with the second chamber; and
a diffusion member disposed between the second chamber and the third chamber and configured to uniformly supply the gas from the second chamber to the third chamber;
wherein the third chamber comprises an internal flow channel having a first end and an opposite second end, the first end being in fluid communication with the second chamber via the diffusion member, the second end being defined by an upright wall and an inclined wall, and the air curtain device being configured to provide the gas toward a substrate carrier at an inclined angle through the second end.

2. The air curtain device according to claim 1, wherein the first end of the internal flow channel has a greater cross-sectional area than the second end, such that the gas passing through the second end has a greater flow velocity than that passing through the first end.

3. The air curtain device according to claim 1, wherein an included angle is formed between the inclined wall and the upright wall, the inclined angle being defined by the included angle, and the included angle being less than or equal to 20 degrees.

4. The air curtain device according to claim 3, wherein the included angle is less than or equal to 5 degrees and greater than or equal to 3 degrees.

5. The air curtain device according to claim 1, further comprising:
a gas feeding tunnel disposed between the first chamber and the second chamber and tapered from the first chamber toward the second chamber so as to uniformly supply the gas from the first chamber to the second chamber.

6. The air curtain device according to claim 1, wherein when the gas is provided toward the substrate carrier at the inclined angle through the second end, the gas is guided toward an exterior of the substrate carrier.

7. The air curtain device according to claim 1, wherein the diffusion member is a porous diffusion plate.

8. The air curtain device according to claim 1, wherein the air curtain device is adapted for use with a load port equipment, and when the substrate carrier is supported and positioned on the load port equipment, the air curtain device is disposed above the substrate carrier and configured to provide the gas downward toward the substrate carrier.

9. An air curtain device, comprising:
a gas inlet channel member being in fluid communication with a gas source and configured to receive a gas, the gas inlet channel member having a first chamber therein;
a cover disposed on a side of the gas inlet channel member and having a second chamber therein that is in fluid communication with the first chamber;
a gas feeding housing disposed on the side of the gas inlet channel member and configured to join with the cover, the gas feeding housing having a third chamber therein that is in fluid communication with the second chamber; and
a diffusion member disposed between the cover and the gas feeding housing and configured to uniformly supply the gas from the second chamber to the third chamber;
wherein the third chamber comprises an internal flow channel having a first end and an opposite second end, the first end being in fluid communication with the second chamber via the diffusion member, the second end being defined by an upright wall and an inclined wall, and the air curtain device being configured to provide the gas toward a substrate carrier at an inclined angle through the second end.

10. The air curtain device according to claim 9, wherein the cover comprises a gas feeding tunnel disposed between the first chamber and the second chamber and tapered from the first chamber toward the second chamber so as to uniformly supply the gas from the first chamber to the second chamber.
